(19) United States
(12) Patent Application Publication
(10) Pub. No.: US 2025/0364413 A1
(43) Pub. Date: Nov. 27, 2025

(54) MANAGING CONNECTION STRUCTURES IN SEMICONDUCTOR DEVICES

(71) Applicant: Yangtze Memory Technologies Co., Ltd., Wuhan (CN)

(72) Inventors: Zhong ZHANG, Wuhan (CN); Yang CHEN, Wuhan (CN); Kun ZHANG, Wuhan (CN); Di WANG, Wuhan (CN); Wenxi ZHOU, Wuhan (CN)

(21) Appl. No.: 18/783,306

(22) Filed: Jul. 24, 2024

(30) Foreign Application Priority Data
May 23, 2024 (CN) 202410658248.0

(51) Int. Cl. H01L 23/528; H10B 41/35; H10B 43/35

(52) U.S. Cl. CPC H01L 23/5283; H10B 41/35; H10B 43/35

(57) ABSTRACT

The present disclosure relates to methods, devices, systems, and techniques for managing connection structures in semiconductor devices. An example semiconductor device includes a first stack of conductive layers and isolating layers alternating with each other along a first direction. A connection region of the semiconductor device is adjacent to an array region of the semiconductor device. The semiconductor device further includes contact structures extending along the first direction. The contact structures include a first contact structure coupled to a first conductive layer of the first stack. The semiconductor device further includes a first connection structure in contact with the first contact structure along a second direction perpendicular to the first direction.

### CROSS-REFERENCE TO RELATED APPLICATIONS

This application claims priority to Chinese Patent Application No. 202410658248.0, filed on May 23, 2024, which is hereby incorporated by reference in its entirety.

### TECHNICAL FIELD

The present disclosure relates to semiconductor devices and fabrication methods thereof.

### BACKGROUND

Semiconductor devices, e.g., memory devices, can have various structures to increase a density of memory cells and lines on a chip. For example, three-dimensional (3D) memory devices are attractive due to their capability to increase an array density by stacking more layers within a similar footprint. A 3D memory device normally includes a memory array of memory cells and peripheral circuits for facilitating operations of the memory array.

### SUMMARY

The present disclosure describes methods, devices, systems, and techniques for managing connection structures in semiconductor devices.

One aspect of the present disclosure features a semiconductor device. The semiconductor device includes a first stack of conductive layers and isolating layers alternating with each other along a first direction. A connection region of the semiconductor device is adjacent to an array region of the semiconductor device. The semiconductor device further includes contact structures extending along the first direction. The contact structures include a first contact structure coupled to a first conductive layer of the first stack. The semiconductor device further includes a first connection structure in contact with the first contact structure along a second direction perpendicular to the first direction.

In some implementations, the semiconductor structure includes a second stack of dielectric layers and isolating layers in the connection region. The first contact structure is in contact with a corresponding first dielectric layer of the second stack.

In some implementations, the first contact structure includes a body extending along the first direction and a base extending along the second direction. The body of the first contact structure has a first portion and a second portion. The second portion of the body of the first contact structure is closer to the base of the first contact structure than the first portion of the body of the first contact structure along the first direction. The second portion of the body of the first contact structure is in contact with the base of the first contact structure.

In some implementations, the first connection structure includes a head and a body connected along the first direction. The body of the first connection structure is in contact with the first portion of the body of the first contact structure along the second direction. The body of the first connection structure extends in the semiconductor device along the first direction.

In some implementations, along the second direction, a size of the body of the first connection structure is greater than a size of the head of the first connection structure.

In some implementations, the contact structures include a second contact structure coupled to a second conductive layer of the first stack. The second contact structure is in contact with a second connection structure along the second direction.

In some implementations, the second contact structure includes a body extending along the first direction and a base extending along the second direction. The body of the second contact structure has a first portion and a second portion. The second portion of the body of the second contact structure is connected to the base of the second contact structure. The second portion of the body of the second contact structure is closer to the base of the second contact structure than the first portion of the body of the second contact structure along the first direction. The first portion of the body of the second contact structure is in contact with a body of a second connection structure along the second direction. The second connection structure further includes a head connected to the body of the second connection structure along the first direction.

In some implementations, a body of the first contact structure is surrounded by a dielectric structure, and the dielectric structure is surrounded by a body of the second contact structure.

In some implementations, the first connection structure is in contact with an inner surface of a body of the first contact structure, and the second connection structure is in contact with an outer surface of a body of the second contact structure.

In some implementations, a dielectric structure is in contact with the inner surface of the body of the first contact structure and the first connection structure.

In some implementations, an inner of the first contact structure is filled with the first connection structure.

In some implementations, one or more third connection structures are in contact with the inner surface of the body of the first contact structure, and one or more fourth connection structures are in contact with the outer surface of the body of the second contact structure.

In some implementations, a cross section of a body of the first contact structure is perpendicular to the first direction and has a ring shape.

Another aspect of the present disclosure features a method of forming a semiconductor device. The method includes forming a semiconductor structure including a first stack of conductive layers and isolating layers alternating with each other along a first direction. A connection region of the semiconductor structure is adjacent to an array region of the semiconductor structure. The method further includes forming contact structures extending along the first direction. The contact structures include a first contact structure coupled to a first conductive layer of the first stack. The method further includes forming a first connection structure in contact with the first contact structure along a second direction perpendicular to the first direction.

In some implementations, forming the semiconductor structure includes forming the first stack of conductive layers and isolating layers and a second stack of dielectric layers and isolating layers alternating with each other along the first direction. The second stack is in the connection region. The second stack is connected to the first stack. The first contact structure extends through a part of the second stack along the first direction.

In some implementations, forming the first connection structure includes: forming a first connection hole that extends into the semiconductor structure along the first direction, where the first connection hole exposes a side surface of the first contact structure; forming a body of the first connection structure in the first connection hole by depositing a conductive material into the first connection hole, where the body of the first connection structure is in contact with the first contact structure along the second direction; and forming a head of the first connection structure, where the head is connected to the body along the first direction.

In some implementations, the first contact structure includes a body extending along the first direction and a base extending along the second direction. The body of the first contact structure has a first portion and a second portion. The second portion of the body of the first contact structure is connected to the base of the first contact structure. The second portion of the body of the first contact structure is closer to the base of the first contact structure than the first portion of the body of the first contact structure along the first direction. The first portion of the body of the first contact structure is in contact with the first connection structure along the second direction.

In some implementations, forming the first connection hole includes forming a first hole by a first etching process, where a dielectric material is between the first hole and the first contact structure; and enlarging the first hole by a second etching process to remove the dielectric material between the first hole and the first contact structure.

In some implementations, the contact structures include a second contact structure coupled to a second conductive layer of the first stack, a body of the first contact structure is surrounded by a dielectric structure, and the dielectric structure is surrounded by a body of the second contact structure.

In some implementations, the method further includes forming a second connection hole that extends into the semiconductor structure along the first direction, where the second connection hole exposes a side surface of the second contact structure; and forming a second connection structure in the second connection hole by depositing the conductive material into the second connection hole, where the second connection structure is in contact with the second contact structure along the second direction.

In some implementations, the first connection structure is in contact with an inner surface of a body of the first contact structure, and the second connection structure is in contact with an outer surface of a body of the second contact structure.

In some implementations, forming the second connection hole includes forming a second hole by the first etching process, where a dielectric material is between the second hole and the second contact structure; and enlarging the second hole by the second etching process to remove the dielectric material between the second hole and the second contact structure.

A further aspect of the present disclosure features a memory system. The memory system includes a memory device and a memory controller coupled to the memory device and configured to control the memory device. The memory device includes a first stack of conductive layers and isolating layers alternating with each other along a first direction. A connection region of the memory device is adjacent to an array region of the memory device. The memory device further includes contact structures extending along the first direction. The contact structures include a first contact structure coupled to a first conductive layer of the first stack. The memory device further includes a first connection structure in contact with the first contact structure along a second direction perpendicular to the first direction.

In some implementations, the first contact structure includes a body extending along the first direction and a base extending along the second direction, the body of the first contact structure has a first portion and a second portion, the second portion of the body of the first contact structure is closer to the base of the first contact structure than the first portion of the body of the first contact structure along the first direction, and the second portion of the body of the first contact structure is in contact with the base of the first contact structure.

In some implementations, the contact structures include a second contact structure coupled to a second conductive layer of the first stack, and the second contact structure is in contact with a second connection structure along the second direction.

In some implementations, a body of the first contact structure is surrounded by a dielectric structure, and the dielectric structure is surrounded by a body of the second contact structure.

### BRIEF DESCRIPTION OF DRAWINGS

FIGS. 1A-1B illustrate an example semiconductor device.

FIGS. 2A-2F illustrate example contact structures and connection structures connected in various ways.

FIGS. 3A-3F illustrate an example process of manufacturing a semiconductor device.

FIG. 4 illustrates a flow chart of an example process of manufacturing a semiconductor device.

FIG. 5 illustrates a block diagram of an example system.

Like reference numbers and designations in the various drawings indicate like elements. It is also to be understood that the various exemplary implementations shown in the figures are merely illustrative representations and are not necessarily drawn to scale.

### DETAILED DESCRIPTION

Due to a demand for cheaper memory devices with a higher density, a memory device (e.g., a 3D NAND flash memory) can be formed to have multiple contact structures arranged in a way such that a part (for example, a metal layer) of one contact structure is inside or surrounded by another contact structure. A size of a landing area of such a contact structure can be limited by factors including a size of a contact hole that contains the metal layer, a thickness (e.g., a size in a horizontal direction) of the metal layer, and a distance between metal layers of adjacent contact structures. The limited size of the landing area can cause difficulty when building a connection line pick up to connect the contact structure to another component (e.g., a control circuit). Since each contact structure can be coupled to a respective word line of the memory device, word line to word line leakage may occur when the size of the landing area of the contact structure is small.

In one or more implementations of the present disclosure, an example semiconductor device is provided. The semiconductor device includes a stack of conductive layers and isolating layers alternating with each other along a vertical direction. A contact structure of the semiconductor device is coupled to a conductive layer of the stack. The semiconductor device further includes a connection structure in contact with the contact structure along a horizontal direction.

Implementations of the present disclosure can provide one or more of the following technical advantages and/or benefits. In the example semiconductor device described above, a landing area for building a connection line pick up for the contact structure is determined by an exposed area of the connection structure. A size (e.g., in the horizontal direction) of the connection structure is not limited by the thickness of the metal layer and the distance between metal layers of adjacent contact structures because the connection structure is in contact with the contact structure along the horizontal direction. Thus, the techniques described in the present disclosure allow a larger landing area for the contact structure, which can mitigate or solve the word line to word line leakage issue, thereby improving the quality and reliability of the semiconductor device. The techniques also can make it easier to manufacture reliable connection lines in the semiconductor device, thereby reducing the fabrication cost and increasing the production yield.

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

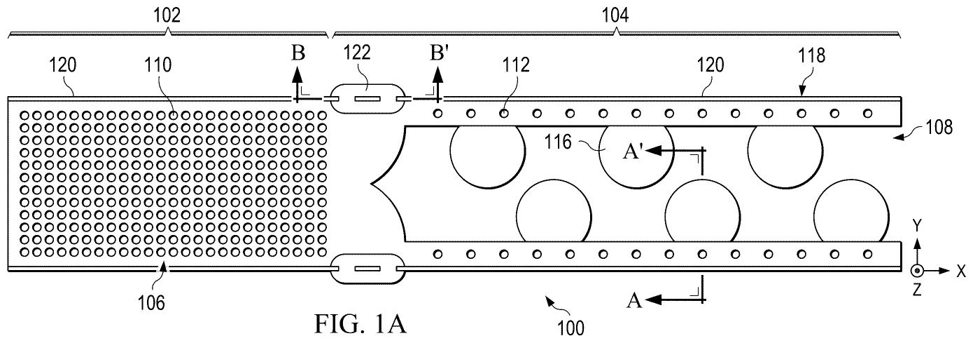

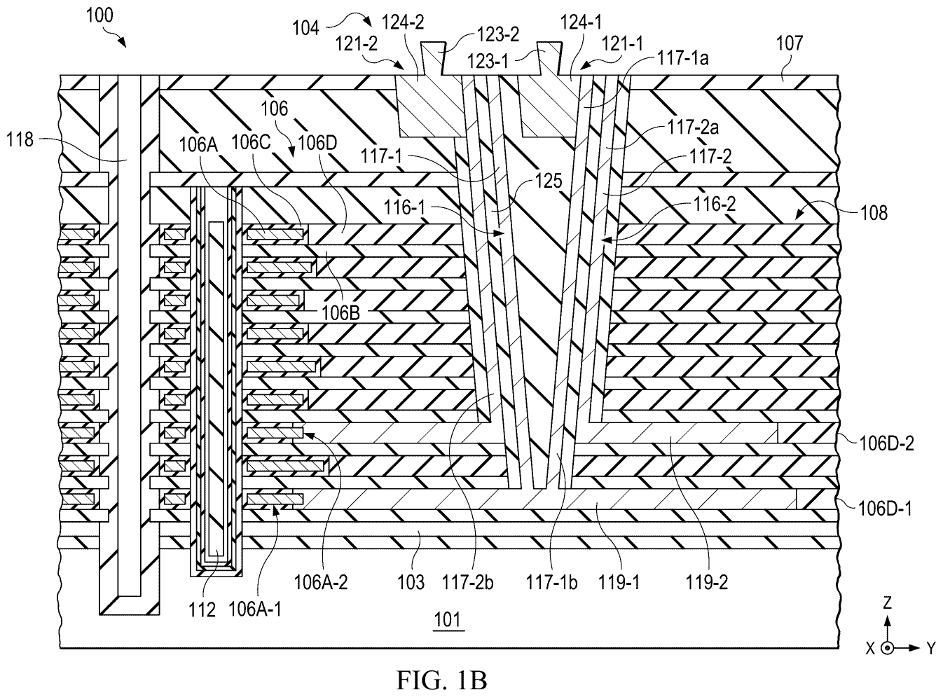

It is noted that X, Y, and Z axes (also referred to as X, Y, and Z directions) are included in FIGS. 1A-1B to further illustrate the spatial relationship of various components in a semiconductor device. A substrate of the semiconductor device can include two lateral surfaces extending laterally in the X-Y plane: a top surface on the front side of the substrate on which a component of the semiconductor device can be formed, and a bottom surface on the backside opposite to the front side of the substrate. The Z direction is perpendicular to both the X and Y directions. As used in the present disclosure, whether one component (e.g., a layer or a device) is “on,” “above,” or “below” another component (e.g., a layer or a device) of the semiconductor device is determined relative to the substrate of the semiconductor device in the Z direction (the vertical direction perpendicular to the X-Y plane, e.g., the thickness direction of the substrate) when the substrate is positioned in the lowest plane of the semiconductor device in the Z direction. The same notion for describing the spatial relationships is applied throughout the present disclosure.

FIG. 1A illustrates a top view of an example semiconductor device 100. In some implementations, the semiconductor device 100 can be a memory device, such as a three-dimensional (3D) NAND memory device. The semiconductor device 100 can include one or more array regions and one or more connection regions configured to provide conductive connections for the one or more array regions. In some implementations, as shown in FIG. 1A, the semiconductor device 100 includes an array region 102 and a connection region 104 adjacent to the array region 102 along a first horizontal direction (e.g., the X direction). It is understood that the example in FIG. 1A is for illustration purpose and is not intended to be construed in a limiting sense. In practice, any suitable arrangement of various regions in the semiconductor device 100 can be applied. In some instances, the semiconductor device 100 can have two connection regions 104 and an array region 102 arranged between the two connection regions 104 along the X direction. In some other instances, the semiconductor device 100 can have two array regions 102 and a connection region 104 between the two array regions 102 along the X direction.

The semiconductor device 100 includes a stack 106 of alternating conductive layers and isolating layers (e.g., conductive layers 106A and isolating layers 106B as shown in FIG. 1B). In some implementations, a part of the stack 106 can be in the array region 102, and another part of the stack 106 can be in the connection region 104. The semiconductor device 100 further includes a stack 108 of alternating dielectric layers and isolating layers (e.g., dielectric layers 106D and isolating layers 106B as shown in FIG. 1B). In some implementations, the stack 108 can be in the connection region 104. The stack 106 is connected to the stack 108.

The semiconductor device 100 can include an array of channel structures 110 extending through the stack 106. In some implementations, the array of channel structures 110 is in the array region 102. Each channel structure 110 can be used to form a string of memory cells coupled in serial along a vertical direction (e.g., Z direction) perpendicular to the first horizontal direction. In some implementations, the semiconductor device 100 can include dummy channel structures 112 (also referred to as dummy memory strings) for process variation control during fabrication and/or for additional mechanical support. The dummy channel structures 112 can extend through the stack 106. In some implementations, the dummy channel structures 112 are in the connection region 104. For example, some dummy channel structures 112 can be in an edge or peripheral area of the connection region 104. In some instances, the edge area of the connection region 104 is adjacent to the array region 102. In some other instances, the edge area of the connection region 104 is adjacent to a gate line structure (e.g., gate line structure 118 as shown in FIG. 1A). In some implementations, the dummy channel structures 112 are in the array region 102 (e.g., an area adjacent to the connection region 104).

The semiconductor device 100 can include contact structures 116. In some implementations, the contact structures 116 are in the connection region 104. A contact structure 116 can be configured to connect one or more corresponding conductive layers of the conductive layers of the stack 106 to a control circuit. The semiconductor device 100 can include one or more gate line structures 118. Each gate line structure 118 can extend in the X direction. The gate line structure 118 can extend into both the array region 102 and the connection region 104. In some implementations, the gate line structures 118 can divide an array region into multiple memory blocks. In some implementations, the gate line structure 118 can function as a common source contact for the channel structures 110 in the array region 102. In some implementations, as shown in FIG. 1A, each gate line structure 118 can include multiple segments 120 extending along the X direction. In some implementations, the segments 120 can be separated and spaced by isolation structures 122 along the X direction. The isolation structures 122 can eliminate or reduce stress built in the gate line structure 118 during the manufacturing process, thereby preventing the gate line structure 118 from bending or cracking. In some implementations, as shown in FIG. 1A, the isolation structure 122 is in the connection region 104 and is adjacent to the array region 102. In some other implementations, the isolation structure 122 is in the array region 102 and is adjacent to the connection region 104. In some other implementations, the isolation structure 122 can have a portion in the array region 102 and another portion in the connection region 104. In some implementations (not shown in FIG. 1A), the gate line structure 118 can further include one or more segments extending along a second horizontal direction (e.g., the Y direction). In some implementations, the gate line structure 118 can include multiple segments connected in an H shape or a T shape. In some implementations, the segments 120 of each gate line structure 118 can have similar or a same width (e.g., along the Y direction). In some other implementations, the segments 120 of each gate line structure 118 can have different widths (e.g., along the Y direction). In some implementations, along the Y direction, a width of the segment 120 in the connection region 104 is larger than a width of the segment 120 in the array region 102. For example, the width of the segment 120 in the connection region 104 can be approximately 1.5 to 2 times that of the segment 120 in the array region 102.

FIG. 1B illustrates a cross-sectional view of the semiconductor device 100 along a cut line AA′ of FIG. 1A. The semiconductor device 100 can include a substrate 101, the stack 106 of alternating conductive layers 106A and isolating layers 106B, and the stack 108 of alternating dielectric layers 106D and isolating layers 106B. Each isolating layer 106B can have a portion between two adjacent conductive layers 106A in the stack 106 and another portion between two adjacent dielectric layers 106D in the stack 108. The stack 106 and the stack 108 are provided over the substrate 101. The substrate 101 can be any suitable semiconductor substrate having any suitable semiconductor material, such as monocrystalline, polycrystalline or single crystalline semiconductor. For example, the substrate 101 can include silicon, silicon germanium (SiGe), germanium (Ge), gallium arsenide (GaAs), silicon on insulator (SOI), germanium on insulator (GOI), gallium nitride, silicon carbide, III-V compound, or any combinations thereof. In some implementations, the semiconductor device 100 can further include a semiconductor layer 103 between the stack 106 and the substrate 101 along the vertical direction. The semiconductor layer 103 can include any suitable semiconductor material (e.g., polysilicon). In some implementations, the substrate 101 and/or the semiconductor layer 103 can be removed from the semiconductor device 100 in a later process of manufacturing the semiconductor device 100. The semiconductor device 100 can include a top layer 107 made of an isolating material (e.g., oxide).

The stack 106 can extend in the second horizontal direction (e.g., the Y direction) that is parallel to a top surface of the substrate 101 and perpendicular to the first horizontal direction (e.g., the X direction). The conductive layers 106A and the isolating layers 106B can alternate in the vertical direction (e.g., Z direction) perpendicular to the second horizontal direction. The conductive layers 106A can be the same or different from each other in thickness, for example, ranging from 10-500 nm, e.g., about 35 nm. The isolating layers 106B can also be the same or different from each other in thickness, for example, ranging from 10-500 nm, e.g., about 25 nm. It should be noted that the number of the conductive layers 106A and the isolating layers 106B shown in FIG. 1B is for illustration only and that any suitable number of the conductive layers 106A and the isolating layers 106B can be included in the stack 106. The conductive layers 106A can include any suitable conducting material, such as tungsten (W), cobalt (Co), copper (Cu), aluminum (Al), titanium nitride (TiN), polycrystalline silicon (polysilicon), doped silicon, silicides, or any combination thereof. The isolating layers 106B can include a dielectric material, such as silicon oxide, silicon nitride, silicon oxynitride, or any combination thereof. In some implementations, the isolating layers 106B can also include high-K dielectric materials, such as hafnium oxide, zirconium oxide, aluminum oxide, tantalum oxide, lanthanum oxide, or any combination thereof.

In some implementations, as illustrated in FIG. 1B, the stack 106 includes liner layers 106C. A liner layer 106C can cover part or all sides of a corresponding conductive layer 106A and be between the conductive layer 106A and two isolating layers 106B adjacent to the corresponding conductive layer 106A. The liner layer 106C can include a high-K dielectric material (e.g., Al₂O₃). In some examples, the conductive layer 106A includes a metallic material (e.g., W) and an adhesive material (e.g., TiN), and the adhesive material can be deposited between the metallic material and the high-K dielectric material. In some examples, the conductive layer 106A includes the metallic material (e.g., W), and the liner layer 106C includes the adhesive material (e.g., TiN) and the high-K dielectric material.

The stack 108 includes dielectric layers 106D and isolating layers 106B alternating with each other along the vertical direction (e.g., Z direction). The stack 108 can be connected to the stack 106. The isolating layers 106B can extend into both the stack 106 and the stack 108 along the second horizontal direction (e.g., Y direction) in the connection region 104. A dielectric layer 106D in the stack 108 can extend to and be in contact with a corresponding conductive layer 106A (or a liner layer 106C surrounding the corresponding conductive layer 106A) in the stack 106. To fabricate the stack 106 and the stack 108, a series of alternating dielectric layers 106D and isolating layers 106B can be first formed. Then, dielectric layers 106D in a region of the stack 106 can be etched away, e.g., through an opening formed in the position of the gate line structure 118, while dielectric layers 106D in the stack 108 remain unchanged. Then, the liner layers 106C and the conductive layers 106A can be formed in replace of the dielectric layers 106D in the region of the stack 106 to form the stack 106.

The gate line structure 118 can extend through the stack 106 along the vertical direction (e.g., the Z direction). In some implementations, as shown in FIG. 1B, the gate line structure 118 can extend from the top layer 107 into the substrate 101 along the Z direction. The dummy channel structure 112 also can extend through the stack 106 along the vertical direction (e.g., the Z direction). In some implementations, as shown in FIG. 1B, the dummy channel structure 112 can extend into the substrate 101 along the Z direction.

Each contact structure 116 can extend through at least a part of the stack 108 (e.g., a set of dielectric layers 106D and isolating layers 106B of the stack 108) along the Z direction. The contact structure 116 can be coupled to one of the conductive layers 106A of the stack 106 and can be in contact with one of the dielectric layers 106D of the stack 108. Multiple contact structures 116 can be arranged in a way such that a part of one contact structure is inside or surrounded by another contact structure. The contact structure 116 can include a body 117 and a base 119. For example, as shown in FIG. 1B, the contact structures 116 can include a contact structure 116-1 and another contact structure 116-2. The contact structure 116-1 can include a body 117-1 extending along the vertical direction (e.g., the Z direction) and a base 119-1 extending along a direction perpendicular to the vertical direction (e.g., in the X-Y plane). The body 117-1 of the contact structure 116-1 has a portion 117-1a and a portion 117-1b. The portion 117-1b of the body 117-1 of the contact structure 116-1 is closer to the base 119-1 of the contact structure 116-1 than the portion 117-1a of the body 117-1 of the contact structure 116-1 along the Z direction. The portion 117-1b of the body 117-1 of the contact structure 116-1 can be in contact with the base 119-1 of the contact structure 116-1. The base 119-1 of the contact structure 116-1 can be in contact with and coupled to a conductive layer 106A-1 of the stack 106 on one side and in contact with a dielectric layer 106D-1 of the stack 108 on another side. The contact structure 116-2 can include a body 117-2 extending along the vertical direction (e.g., the Z direction) and a base 119-2 extending along a direction perpendicular to the vertical direction (e.g., in the X-Y plane). The body 117-2 of the contact structure 116-2 has a portion 117-2a and a portion 117-2b. The portion 117-2b of the body 117-2 of the contact structure 116-2 is closer to the base 119-2 of the contact structure 116-2 than the portion 117-2a of the body 117-2 of the contact structure 116-2 along the Z direction. The portion 117-2b of the body 117-2 of the contact structure 116-2 can be in contact with the base 119-2 of the contact structure 116-2. The base 119-2 of the contact structure 116-2 can be in contact with and coupled to a conductive layer 106A-2 of the stack 106 on one side and in contact with a dielectric layer 106D-2 of the stack 108 on another side. In some implementations, a cross section (e.g., in the X-Y plane) of the body of the contact structure 116-1 or 116-2 can be in a ring shape. As shown in FIG. 1B, the body 117-1 of the contact structure 116-1 can be surrounded by a dielectric structure 125. The dielectric structure 125 can be surrounded by the body 117-2 of the contact structure 116-2. The dielectric structure 125 can include any suitable dielectric material, such as silicon oxide, silicon nitride, silicon oxynitride, or any combination thereof.

Each contact structure 116 can be in contact with one or more connection structures 121. For example, a connection structure 121-1 can be in contact with the contact structure 116-1 along a direction perpendicular to the vertical direction (e.g., in the X-Y plane). In some implementations, as shown in FIG. 1B, the connection structure 121-1 includes a head 123-1 and a body 124-1 connected along the Z direction. The body 124-1 of the connection structure 121-1 is in contact with the portion 117-la of the body 117-1 of the contact structure 116-1 along a horizontal direction. The body 124-1 of the connection structure 121-1 extends in the semiconductor device 100 along the vertical direction. In some implementations, along a horizontal direction, a size of the body 124-1 of the connection structure 121-1 is greater than a size of the head 123-1 of the connection structure 121-1. A connection structure 121-2 can be in contact with the contact structure 116-2 along a direction perpendicular to the vertical direction (e.g., in the X-Y plane). In some implementations, as shown in FIG. 1B, the connection structure 121-2 includes a head 123-2 and a body 124-2 connected along the Z direction. The body 124-2 of the connection structure 121-2 is in contact with the portion 117-2a of the body 117-2 of the contact structure 116-2 along a horizontal direction. The body 124-2 of the connection structure 121-2 extends in the semiconductor device 100 along the vertical direction. In some implementations, along a horizontal direction, a size of the body 124-2 of the connection structure 121-2 is greater than a size of the head 123-2 of the connection structure 121-2.

In some implementations, as shown in FIG. 1B, a top surface (e.g., a horizontal surface that is farther away from the substrate 101 along the vertical direction) of the body 124-1 of the connection structure 121-1 can be aligned with a top end of the portion 117-1a of the contact structure 116-1. In some implementations, the head 123-1 of the connection structure 121-1 is on top of the body 124-1 of the connection structure 121-1. The connection structure 121 can be configured to couple a corresponding contact structure 116 to another component (e.g., a control circuit). The connection structure 121 can include any suitable conductive material, such as W, Co, Cu, Al, TiN, polysilicon, doped silicon, silicides, or any combination thereof.

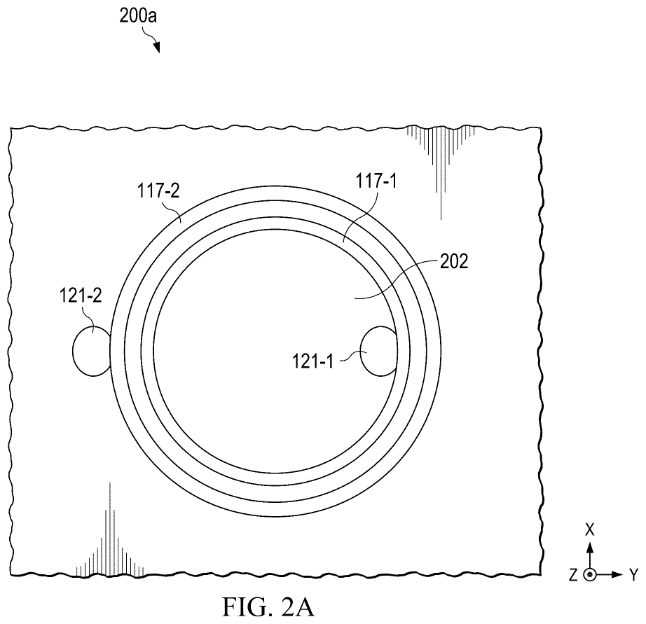

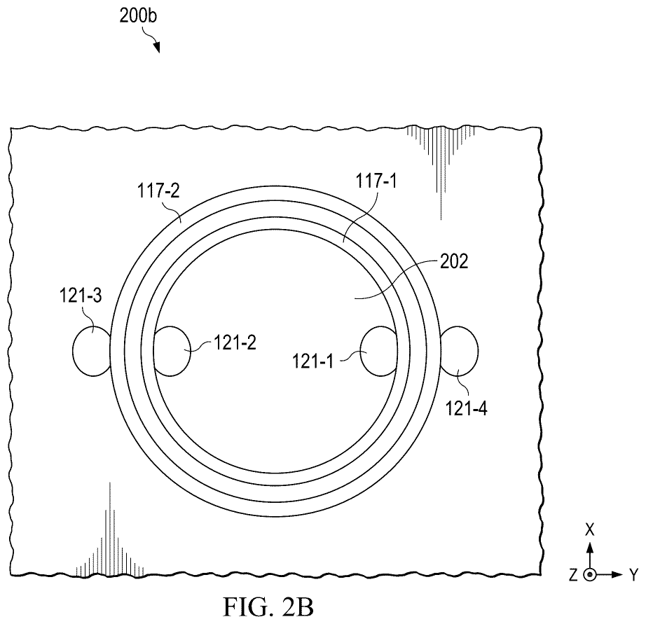

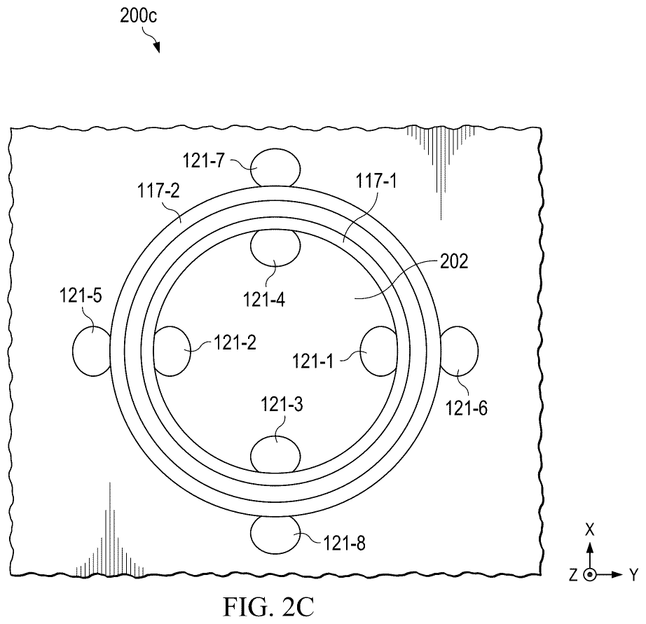

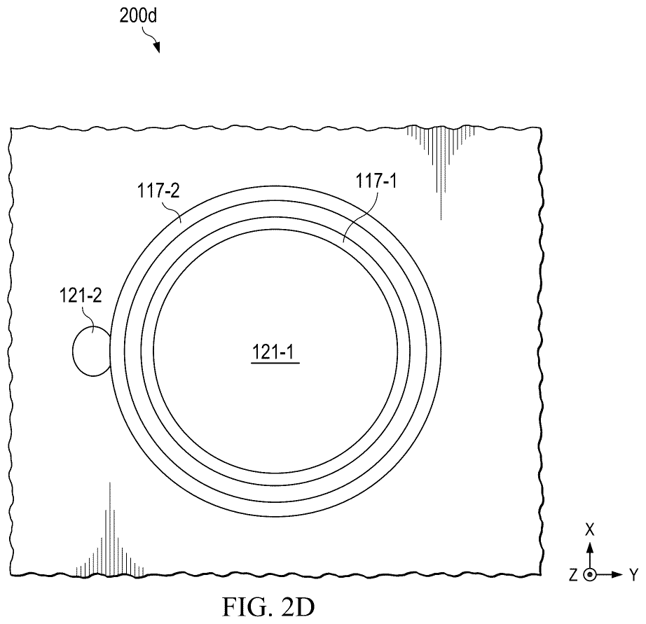

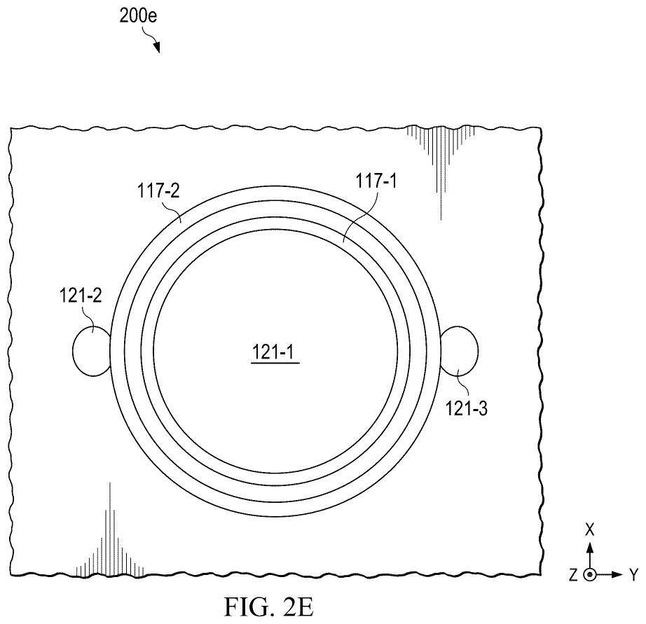

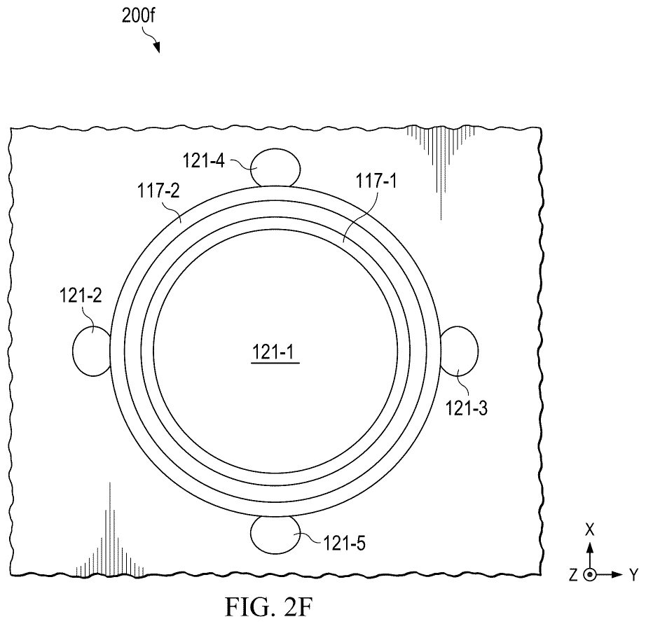

FIGS. 2A-2F illustrate top views of example contact structures and connection structures (e.g., contact structures 116 and connection structures 121 of FIG. 1B) connected in various ways. It is understood that the examples in FIGS. 2A-2F are for illustration purpose and are not intended to be construed in a limiting sense, and that any suitable numbers of connection structures and contact structures can be applied in practice.

As shown in a semiconductor structure 200a of FIG. 2A, the connection structure 121-1 is in contact with an inner surface of the body 117-1 of the contact structure 116-1. The connection structure 121-2 is in contact with an outer surface of the body 117-2 of the contact structure 116-2. A dielectric structure 202 is in contact with the inner surface of the body 117-1 of the contact structure 116-1 and the connection structure 121-1. While FIG. 2A (and one or more other figures of the present disclosure) illustrates that a cross section (e.g., a horizontal cross section) of a connection structure (e.g., the body of the connection structure 121-1 or 121-2) is in a circle shape or oval shape, it is understood that any other suitable shapes such as square and rectangle can also be applied in practice.

As shown in a semiconductor structure 200b of FIG. 2B, two connection structures 121-1 and 121-2 are in contact with the inner surface of the body 117-1 of the contact structure 116-1. The connection structures 121-1 and 121-2 are arranged along a direction (e.g., the Y direction) and opposite to each other. Two connection structures 121-3 and 121-4 are in contact with the outer surface of the body 117-2 of the contact structure 116-2. The connection structures 121-3 and 121-4 also are arranged along a direction (e.g., the Y direction) and opposite to each other.

As shown in a semiconductor structure 200c of FIG. 2C, four connection structures 121-1 to 121-4 are in contact with the inner surface of the body 117-1 of the contact structure 116-1. The connection structures 121-1 and 121-2 are arranged along a direction (e.g., the Y direction) and opposite to each other. The connection structures 121-3 and 121-4 are arranged along another direction (e.g., the X direction) and opposite to each other. Four connection structure 121-5 to 121-8 are in contact with the outer surface of the body 117-2 of the contact structure 116-2. The connection structures 121-5 and 121-6 are arranged along a direction (e.g., the Y direction) and opposite to each other. The connection structures 121-7 and 121-8 are arranged along another direction (e.g., the X direction) and opposite to each other.

As shown in a semiconductor structure 200d of FIG. 2D, the connection structure 121-1 is in contact with the inner surface of the body 117-1 of the contact structure 116-1. Specifically, an inner of the body 117-1 is filled with the connection structure 121-1. The connection structure 121-2 is in contact with the outer surface of the body 117-2 of the contact structure 116-2.

As shown in a semiconductor structure 200e of FIG. 2E, the inner of the body 117-1 is filled with the connection structure 121-1. The connection structures 121-2 and 121-3 are in contact with the outer surface of the body 117-2 of the contact structure 116-2. The connection structures 121-2 and 121-3 are arranged along a direction (e.g., the Y direction) and opposite to each other.

As shown in a semiconductor structure 200f of FIG. 2F, the inner of the body 117-1 is filled with the connection structure 121-1. Four connection structure 121-2 to 121-5 are in contact with the outer surface of the body 117-2 of the contact structure 116-2. The connection structures 121-2 and 121-3 are arranged along a direction (e.g., the Y direction) and opposite to each other. The connection structures 121-4 and 121-5 are arranged along another direction (e.g., the X direction) and opposite to each other.

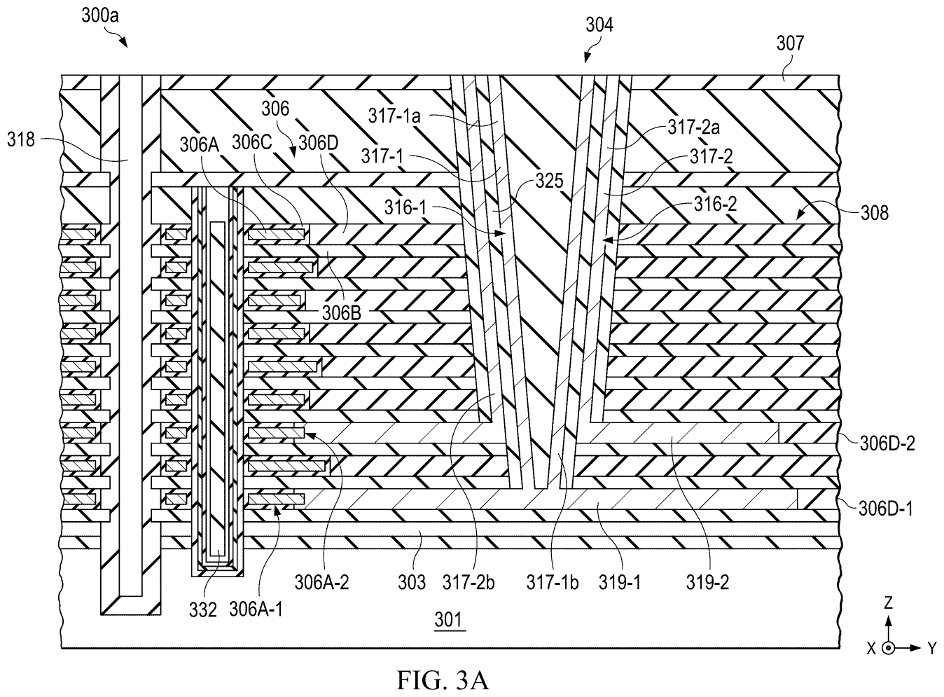

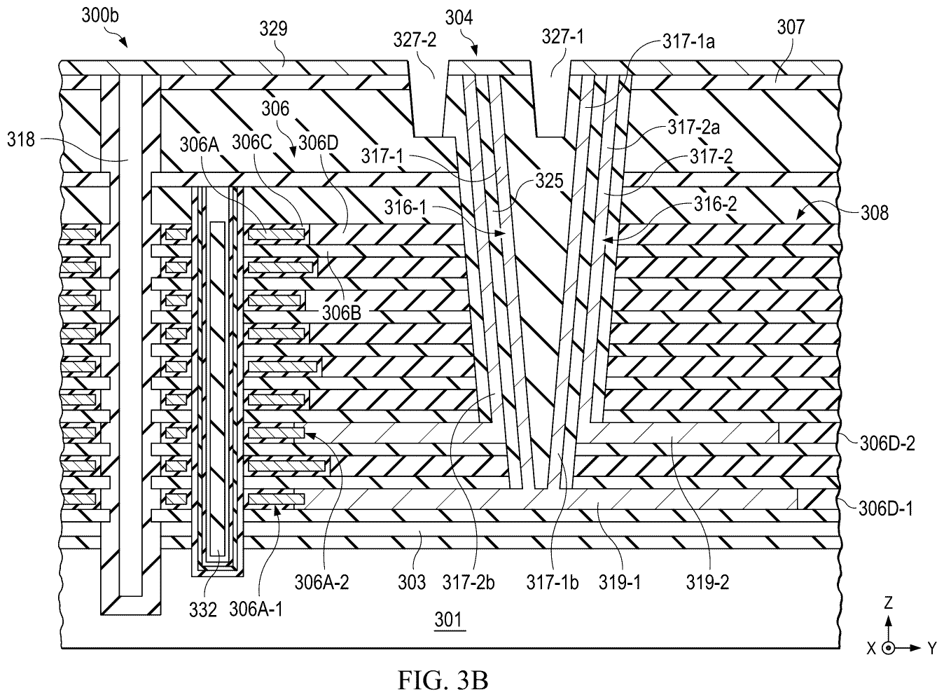

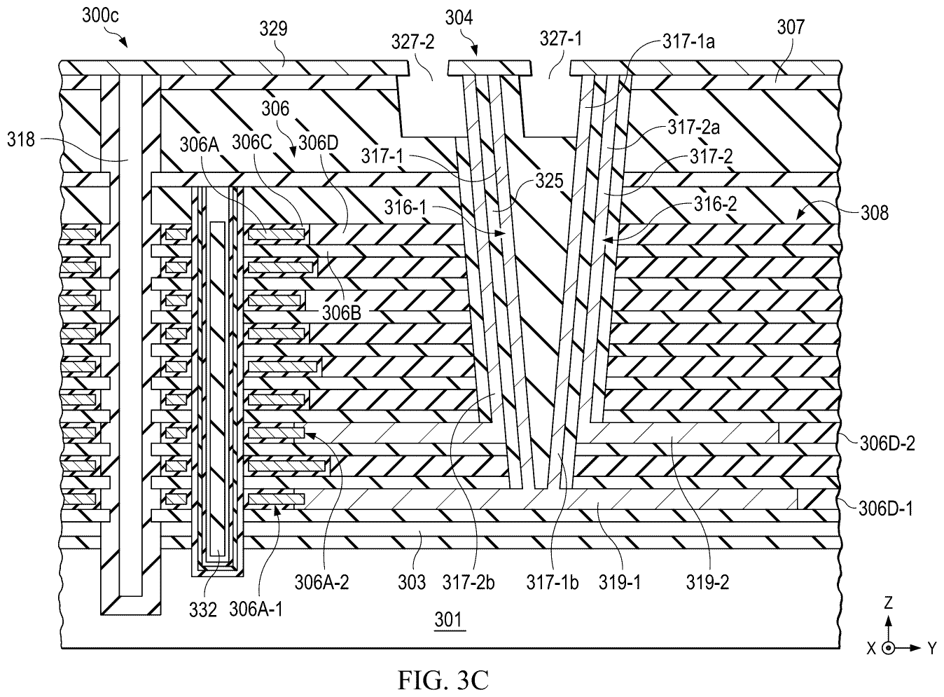

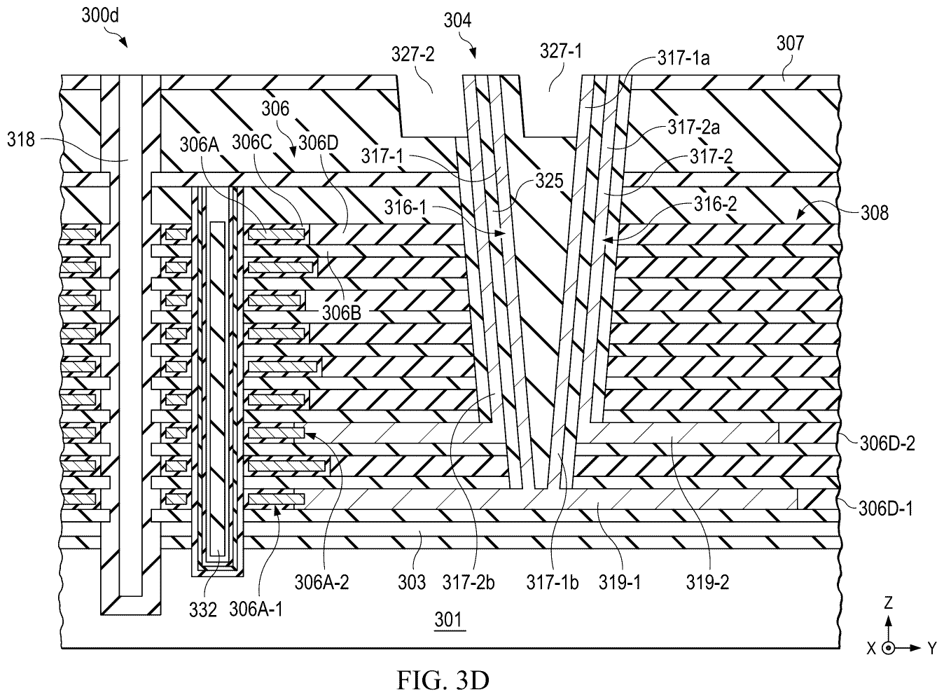

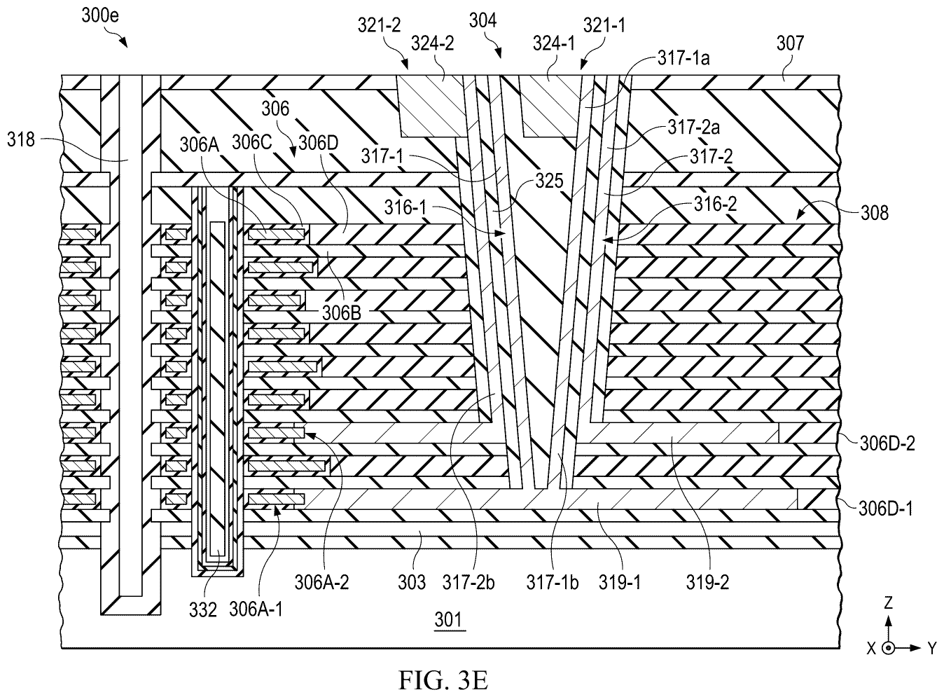

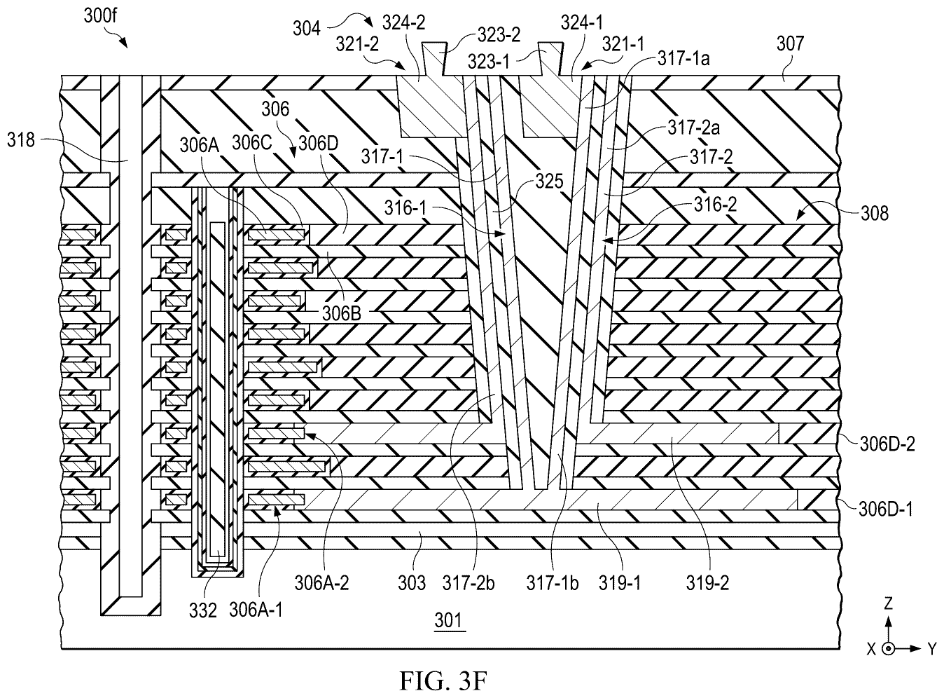

FIGS. 3A-3F illustrate an example process of fabricating a semiconductor device, such as the semiconductor device 100 as illustrated in FIGS. 1A-1B and 2A-2F. FIGS. 3A-3F show cross-sectional views of example semiconductor structures along the cut line AA′ of FIG. 1A at various stages of the fabrication process.

As shown in FIG. 3A, a semiconductor structure 300a is formed. The semiconductor structure 300a can be same as, or similar to, the semiconductor device 100 of FIGS. 1A-1B, except that connection structures are not formed in the semiconductor structure 300a yet. For example, an array region 302 (not shown) of the semiconductor structure 300a can be same as, or similar to, the array region 102 of FIG. 1A, and a connection region 304 of the semiconductor structure 300a can be same as, or similar to, the connection region 104 of FIGS. 1A-1B. A substrate 301 of the semiconductor structure 300a can be same as, or similar to, the substrate 101 of FIG. 1B. A stack 306 of alternating conductive layers 306A and isolating layers 306B of the semiconductor structure 300a can be same as, or similar to, the stack 106 of FIG. 1B. A stack 308 of alternating dielectric layers 306D and isolating layers 306B of the semiconductor structure 300a can be same as, or similar to the stack 108 of FIG. 1B. Contact structures 316 (e.g., contact structures 316-1 and 316-2) of the semiconductor structure 300a can be same as, or similar to the contact structures 116 (e.g., contact structures 116-1 and 116-2) of FIGS. 1A-1B.

As shown in FIG. 3B, a semiconductor structure 300b is formed. The semiconductor structure 300b include connection holes 327 (e.g., connection holes 327-1 and 327-2) extending along the Z direction. The connection holes 327-1 and 327-2 can be formed by a first etching process using an etching mask 329 (e.g., a sacrificial film deposited on top of the semiconductor structure 300a) with patterns designed for these holes. The connection holes 327-1 and 327-2 can extend from a top surface of the semiconductor structure 300b into the semiconductor structure 300b along the Z direction. The connection hole 327-1 is adjacent to an inner surface of a body 317-1 (e.g., a top portion 317-1a) of the contact structure 316-1 along a horizontal direction (e.g., in the X-Y plane). In some implementations, a dielectric material (e.g., silicon oxide) can be between the connection hole 327-1 and the body 317-1 along the horizontal direction. The connection hole 327-2 is adjacent to an outer surface of a body 317-2 (e.g., a top portion 317-2a) of the contact structure 316-2 along a horizontal direction (e.g., in the X-Y plane). In some implementations, a dielectric material (e.g., silicon oxide) can be between the connection hole 327-2 and the body 317-2 along the horizontal direction.

As shown in FIG. 3C, a semiconductor structure 300c is formed by a second etching process. The second etching process enlarges the connection holes 327-1 and 327-2 by etching off the dielectric material between the connection hole 327-1 and the body 317-1 and between the connection hole 327-2 and the body 317-2. The enlarged connection hole 327-1 exposes a side surface (e.g., an inner surface as shown in FIG. 3C) of the body 317-1 of the contact structure 316-1. The enlarged connection hole 327-2 exposes a side surface (e.g., an outer surface as shown in FIG. 3C) of the body 317-2 of the contact structure 316-2.

As shown in FIG. 3D, a semiconductor structure 300d is formed by removing the etching mask 329.

As shown in FIG. 3E, a semiconductor structure 300e is formed. The semiconductor structure 300e includes connection structures 321. The connection structures 321 include connection structures 321-1 and 321-2. A body 324-1 of the connection structure 321-1 is in the connection hole 327-1, and a body 324-2 of the connection structure 321-2 is in the connection hole 327-2. The body 324-1 of the connection structure 321-1 and the body 324-2 of the connection structure 321-2 can be formed by, for example, depositing a conductive material (e.g., W) into the connection holes 327-1 and 327-2. The body 324-1 of the connection structure 321-1 is in contact with the contact structure 316-1 (e.g., the top portion 317-1a of the body 317-1) along a horizontal direction (e.g., the Y direction). The body 324-2 of the connection structure 321-2 is in contact with the contact structure 316-2 (e.g., the top portion 317-2a of the body 317-2) along the horizontal direction (e.g., the Y direction).

FIG. 3F illustrates a semiconductor structure 300f including a head 323-1 of the connection structure 321-1 and a head 323-2 of the connection structure 321-2. The head 323-1 of the connection structure 321-1 is connected to the body 324-1 of the connection structure 321-1 along the vertical direction. The head 323-2 of the connection structure 321-2 is connected to the body 324-2 of the connection structure 321-2 along the vertical direction. The heads 323-1 and 323-2 can be formed, for example, by depositing a sacrificial layer on top of the semiconductor structure 300e, forming holes (e.g., by etching) extending through the sacrificial layer to the bodies 324-1 and 324-2, depositing a conductive material into the holes, and removing the sacrificial layer to expose the heads 323-1 and 323-2. The connection structures 321 (e.g., connection structures 321-1 and 321-2) can be examples of the connection structures 116 of FIGS. 1A-1B. Although FIGS. 3A-3F illustrate the process of forming two connection structures 321-1 and 321-2, other example connection structures 321, such as the ones described with reference to FIGS. 2A-2F, also can be formed using suitable variations of the above process.

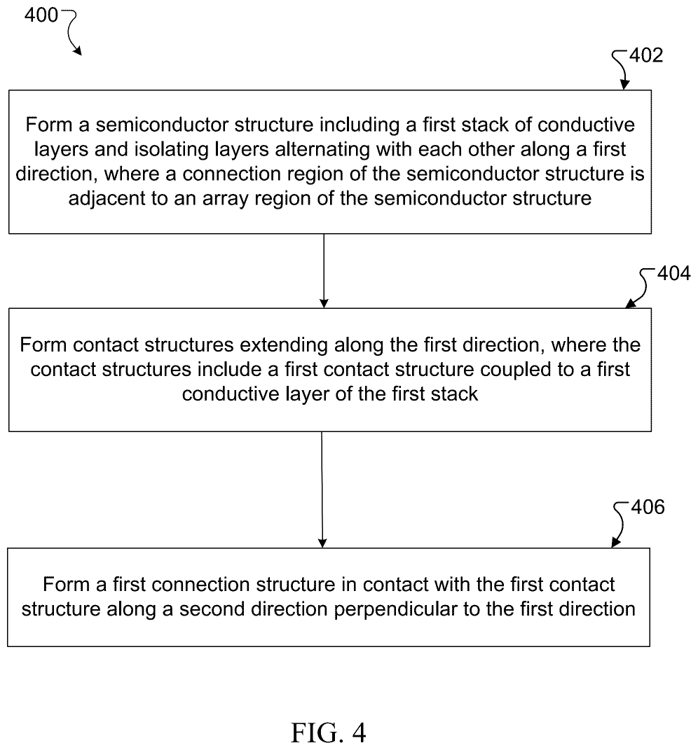

FIG. 4 illustrates a flow chart of an example process 400. The process 400 can be performed to form a semiconductor device (e.g., the semiconductor device 100 illustrated by FIGS. 1A-1B). The process 400 can be described in view of FIGS. 3A-3F. The process 400 can include one or more steps of the fabrication process of forming the semiconductor structures in FIGS. 3A-3F. It is understood that the operations shown in process 400 are not exhaustive and that other operations can be performed as well before, after, or between any of the illustrated operations. Further, some of the operations may be performed simultaneously, or in a different order than shown in FIG. 4.

At operation 402, a semiconductor structure (e.g., the semiconductor structure 300a of FIG. 3A) is formed. The semiconductor structure includes a first stack (e.g., the stack 306 of FIG. 3A) of conductive layers (e.g., the conductive layers 306A) and isolating layers (e.g., the isolating layers 306B) alternating with each other along a first direction (e.g., the Z direction). A connection region (e.g., connection region 304 of FIG. 3A) of the semiconductor structure is adjacent to an array region (e.g., array region 302) of the semiconductor structure.

At operation 404, contact structures (e.g., the contact structures 316 of FIG. 3A) extending along the first direction are formed. The contact structures include a first contact structure (e.g., the contact structure 316-1 of FIG. 3A) coupled to a first conductive layer (e.g., the conductive layer 306A-1 of FIG. 3A) of the first stack (e.g., the stack 306 of FIG. 3A).

At operation 406, a first connection structure (e.g., the connection structure 321-1 of FIG. 3F) is formed. The first connection structure is in contact with the first contact structure along a second direction (e.g., a horizontal direction in the X-Y plane) perpendicular to the first direction.

In some implementations, forming the semiconductor structure includes forming the first stack (e.g., the stack 306) of conductive layers and isolating layers and a second stack (e.g., the stack 308 of FIG. 3A) of dielectric layers (e.g., the dielectric layers 306D of FIG. 3A) and isolating layers (e.g., the isolating layers 306B of FIG. 3A) alternating with each other along the first direction. The second stack can be in the connection region. The second stack can be connected to the first stack. The first contact structure (e.g., the body 317-1 of the contact structure 316-1 of FIG. 3A) extends through a part of the second stack along the first direction.

In some implementations, forming the first connection structure includes forming a first connection hole (e.g., the connection hole 327-1 of FIG. 3D) that extends into the semiconductor structure along the first direction. The first connection hole exposes a side surface of the first contact structure (e.g., the inner surface of the body 317-1 of the contact structure 316-1 of FIG. 3D).

In some implementations, forming the first connection hole includes forming a first hole (e.g., the connection hole 327-1 of FIG. 3B) by a first etching process (e.g., as described with reference to FIG. 3B). A dielectric material is between the first hole and the first contact structure. Forming the first connection hole further includes enlarging the first hole by a second etching process to remove the dielectric material between the first hole and the first contact structure (e.g., as described with reference to FIG. 3C).

In some implementations, forming the first connection structure further includes forming a body (e.g., the body 324-1 of FIG. 3E) of the first connection structure in the first connection hole (e.g., the connection hole 327-1 of FIG. 3E) by depositing a conductive material into the first connection hole. The body of the first connection structure is in contact with the first contact structure along the second direction. Forming the first connection structure further includes forming a head (e.g., the head 323-1) of the first connection structure. The head is connected to the body along the first direction.

In some implementations, the first contact structure includes a body (e.g., the body 317-1 of FIG. 3A) extending along the first direction and a base (e.g., the base 319-1 of FIG. 3A) extending along the second direction. The body of the first contact structure has a first portion (e.g., the portion 317-1a of FIG. 3A) and a second portion (e.g., the portion 317-1b of FIG. 3A). The second portion of the body of the first contact structure is connected to the base of the first contact structure. The second portion of the body of the first contact structure is closer to the base of the first contact structure than the first portion of the body of the first contact structure along the first direction. The first portion of the body of the first contact structure is in contact with the first connection structure along the second direction (e.g., as shown in FIGS. 3E and 3F).

In some implementations, the contact structures include a second contact structure (e.g., the contact structure 316-2 of FIG. 3A) coupled to a second conductive layer (e.g., the conductive layer 306A-2 of FIG. 3A) of the first stack. A body (e.g., the body 317-1 of FIG. 3A) of the first contact structure is surrounded by a dielectric structure (e.g., the dielectric structure 325 of FIG. 3A), and the dielectric structure is surrounded by a body (e.g., the body 317-2 of FIG. 3A) of the second contact structure.

In some implementations, the process 400 further includes forming a second connection hole (e.g., the connection hole 327-2 of FIG. 3D) that extends into the semiconductor structure along the first direction. The second connection hole exposes a side surface (e.g., an outer surface of the body 317-2 of the contact structure 316-2 of FIG. 3D) of the second contact structure. The process 400 further includes forming a second connection structure (e.g., the connection structure 321-2 of FIG. 3F) in the second connection hole by depositing the conductive material into the second connection hole. The second connection structure is in contact with the second contact structure along the second direction.

In some implementations, forming the second connection hole includes forming a second hole (e.g., the connection hole 327-2 of FIG. 3B) by the first etching process (e.g., as described with reference to FIG. 3B). A dielectric material is between the second hole and the second contact structure. Forming the second connection hole further includes enlarging the second hole by the second etching process to remove the dielectric material between the second hole and the second contact structure (e.g., as described with reference to FIG. 3C).

In some implementations, the first connection structure is in contact with an inner surface of a body (e.g., the body 317-1 of FIG. 3F) of the first contact structure, and the second connection structure is in contact with an outer surface of a body (e.g., the body 317-2 of FIG. 3F) of the second contact structure.

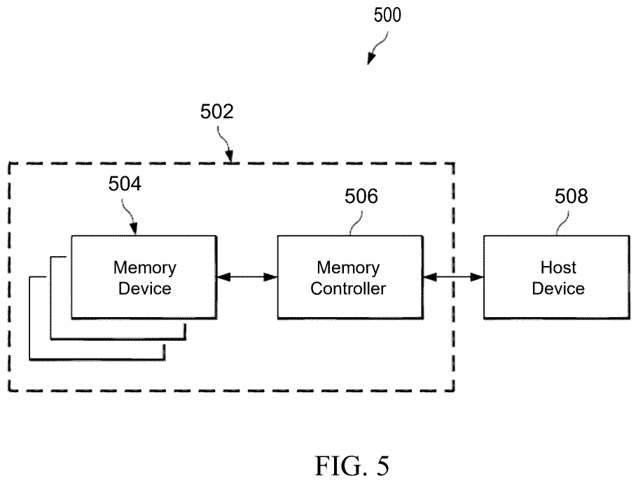

FIG. 5 illustrates a block diagram of an example system 500. The system 500 can have one or more semiconductor devices (e.g., memory devices), according to one or more implementations of the present disclosure. The system 500 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage. As shown in FIG. 5, the system 500 can include a host device 508 and a memory system 502 having one or more memory devices 504 and a memory controller 506. Host device 508 can include a processor of an electronic device, such as a central processing unit (CPU), or a system-on-chip (SoC), such as an application processor (AP). Host device 508 can be configured to send or receive data to or from the one or more memory devices 504.

A memory device 504 can be any memory device disclosed in the present disclosure, such as a memory device (e.g., a NAND Flash memory) as shown in FIGS. 1A-1B. Memory controller 506 (a.k.a., a controller circuit) is coupled to memory device 504 and host device 508. Consistent with implementations of the present disclosure, memory device 504 can include a plurality of conductive interconnections through a cover layer that are in contact with conductive pads in a conductive pad layer, and memory controller 506 can be coupled to memory device 504 through at least one of the plurality of conductive interconnections. Memory controller 506 is configured to control memory device 504. For example, memory controller 506 may be configured to operate a plurality of channel structures via word lines. Memory controller 506 can manage data stored in memory device 504 and communicate with host device 508.

In some implementations, memory controller 506 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 506 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 506 can be configured to control operations of memory device 504, such as read, erase, and program (or write) operations. Memory controller 506 can also be configured to manage various functions with respect to the data stored or to be stored in memory device 504 including, but not limited to bad-block management, garbage collection, logical-to-physical address conversion, wear leveling, etc. In some implementations, memory controller 506 is further configured to process error correction codes (ECCs) with respect to the data read from or written to memory device 504. Any other suitable functions may be performed by memory controller 506 as well, for example, formatting memory device 504.

Memory controller 506 can communicate with an external device (e.g., host device 508) according to a particular communication protocol. For example, memory controller 506 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 506 and one or more memory devices 504 can be integrated into various types of storage devices, for example, be included in the same package, such as a universal Flash storage (UFS) package or an eMMC package. That is, memory system 502 can be implemented and packaged into different types of end electronic products. In one example as shown in FIG. 5, memory controller 506 and a single memory device 504 may be integrated into a memory card 502. Memory card 502 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically noN+ conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., .+−.10%, .+−.20%, or .+−.30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising:
a first stack of conductive layers and isolating layers alternating with each other along a first direction, wherein a connection region of the semiconductor device is adjacent to an array region of the semiconductor device;
contact structures extending along the first direction, wherein the contact structures comprise a first contact structure coupled to a first conductive layer of the first stack; and
a first connection structure in contact with the first contact structure along a second direction perpendicular to the first direction.

2. The semiconductor device of claim 1, wherein the first contact structure comprises a body extending along the first direction and a base extending along the second direction, the body of the first contact structure has a first portion and a second portion, the second portion of the body of the first contact structure is closer to the base of the first contact structure than the first portion of the body of the first contact structure along the first direction, and the second portion of the body of the first contact structure is in contact with the base of the first contact structure.

3. The semiconductor device of claim 2, wherein the first connection structure comprises a head and a body connected along the first direction, the body of the first connection structure is in contact with the first portion of the body of the first contact structure along the second direction, the body of the first connection structure extends in the semiconductor device along the first direction.

4. The semiconductor device of claim 1, wherein the contact structures comprise a second contact structure coupled to a second conductive layer of the first stack, and wherein the second contact structure is in contact with a second connection structure along the second direction.

5. The semiconductor device of claim 4, wherein a body of the first contact structure is surrounded by a dielectric structure, and the dielectric structure is surrounded by a body of the second contact structure.

6. The semiconductor device of claim 4, wherein the first connection structure is in contact with an inner surface of a body of the first contact structure, and the second connection structure is in contact with an outer surface of a body of the second contact structure.

7. The semiconductor device of claim 6, wherein a dielectric structure is in contact with the inner surface of the body of the first contact structure and the first connection structure.

8. The semiconductor device of claim 6, wherein an inner of the first contact structure is filled with the first connection structure.

9. The semiconductor device of claim 6, wherein one or more third connection structures are in contact with the inner surface of the body of the first contact structure, and one or more fourth connection structures are in contact with the outer surface of the body of the second contact structure.

10. A method for forming a semiconductor device, the method comprising:
forming a semiconductor structure comprising a first stack of conductive layers and isolating layers alternating with each other along a first direction, wherein a connection region of the semiconductor structure is adjacent to an array region of the semiconductor structure;
forming contact structures extending along the first direction, wherein the contact structures comprise a first contact structure coupled to a first conductive layer of the first stack; and
forming a first connection structure in contact with the first contact structure along a second direction perpendicular to the first direction.

11. The method of claim 10, wherein the first contact structure comprises a body extending along the first direction and a base extending along the second direction, the body of the first contact structure has a first portion and a second portion, the second portion of the body of the first contact structure is connected to the base of the first contact structure, the second portion of the body of the first contact structure is closer to the base of the first contact structure than the first portion of the body of the first contact structure along the first direction, and the first portion of the body of the first contact structure is in contact with the first connection structure along the second direction.

12. The method of claim 10, wherein forming the first connection hole comprises:
forming a first hole by a first etching process, wherein a dielectric material is between the first hole and the first contact structure; and
enlarging the first hole by a second etching process to remove the dielectric material between the first hole and the first contact structure.

13. The method of claim 12, wherein the contact structures comprise a second contact structure coupled to a second conductive layer of the first stack, a body of the first contact structure is surrounded by a dielectric structure, and the dielectric structure is surrounded by a body of the second contact structure.

14. The method of claim 13, further comprising:
forming a second connection hole that extends into the semiconductor structure along the first direction, wherein the second connection hole exposes a side surface of the second contact structure; and
forming a second connection structure in the second connection hole by depositing the conductive material into the second connection hole, wherein the second connection structure is in contact with the second contact structure along the second direction.

15. The method of claim 14, wherein the first connection structure is in contact with an inner surface of a body of the first contact structure, and the second connection structure is in contact with an outer surface of a body of the second contact structure.

16. The method of claim 14, wherein forming the second connection hole comprises:
forming a second hole by the first etching process, wherein a dielectric material is between the second hole and the second contact structure; and
enlarging the second hole by the second etching process to remove the dielectric material between the second hole and the second contact structure.

17. A memory system, comprising:
a memory device; and
a memory controller coupled to the memory device and configured to control the memory device,
wherein the memory device comprises:
a first stack of conductive layers and isolating layers alternating with each other along a first direction, wherein a connection region of the memory device is adjacent to an array region of the memory device;
contact structures extending along the first direction, wherein the contact structures comprise a first contact structure coupled to a first conductive layer of the first stack; and
a first connection structure in contact with the first contact structure along a second direction perpendicular to the first direction.

18. The memory system of claim 17, wherein the first contact structure comprises a body extending along the first direction and a base extending along the second direction, the body of the first contact structure has a first portion and a second portion, the second portion of the body of the first contact structure is closer to the base of the first contact structure than the first portion of the body of the first contact structure along the first direction, and the second portion of the body of the first contact structure is in contact with the base of the first contact structure.

19. The memory system of claim 17, wherein the contact structures comprise a second contact structure coupled to a second conductive layer of the first stack, and wherein the second contact structure is in contact with a second connection structure along the second direction.

20. The memory system of claim 19, wherein a body of the first contact structure is surrounded by a dielectric structure, and the dielectric structure is surrounded by a body of the second contact structure.
